(19) United States
(12) Patent Application Publication
(10) Pub. No.: US 2019/0287919 A1
(43) Pub. Date: Sep. 19, 2019

(54) SEMICONDUCTOR DEVICE

(71) Applicant: TOSHIBA MEMORY CORPORATION, Tokyo (JP)

(72) Inventor: Yuichi SANO, Yokohama Kanagawa (JP)

(21) Appl. No.: 16/120,413

(22) Filed: Sep. 3, 2018

(30) Foreign Application Priority Data
Mar. 15, 2018 (JP) 2018-048308

(51) Int. Cl. H01L 23/552; H01L 23/498; H01L 23/31; H01L 21/56

(52) U.S. Cl. CPC H01L 23/552; H01L 23/49838; H01L 25/0657; H01L 21/56; H01L 23/3128

(57) ABSTRACT

According to one embodiment, a semiconductor device includes a substrate including a substrate receiving surface, a side surface, and at least two ground wirings embedded therein and extending to, and exposed at, the side surface, a semiconductor chip mounted on the receiving surface of the substrate, a sealing resin layer over the substrate and the semiconductor chip, the sealing resin layer having an outer surface comprising an upper surface and a side surface, and a conductive shield layer located on the upper surface of the sealing resin layer, the side surface of the sealing resin layer, and the side surface of the substrate, and connected to the at least two ground wirings exposed at the side surface of the substrate, wherein the at least two ground wirings are separated from each other within the substrate, and connected to each other along the side surface of the substrate.

### CROSS-REFERENCE TO RELATED APPLICATION

This application is based upon and claims the benefit of priority from Japanese Patent Application No. 2018-048308, filed Mar. 15, 2018, the entire contents of which are incorporated herein by reference.

### FIELD

Embodiments described herein relate generally to a semiconductor device.

### BACKGROUND

Examples of related art include a shield layer which may be provided in an upper surface and a side surface of a semiconductor package. The shield layer is grounded via a ground wiring provided in a mounting substrate to prevent electromagnetic noise generated in the semiconductor package leak to the outside. However, it is desired to further reduce the leakage of the electromagnetic noise.

### DESCRIPTION OF THE DRAWINGS

FIG. 1 is a cross-sectional view illustrating an example of a configuration of a semiconductor device according to a first embodiment;

FIGS. 2A and 2B are cross-sectional views of a wiring layer in a side surface of a mounting substrate illustrated in FIG. 1;

FIGS. 3A and 3B are cross-sectional views illustrating an exemplary configuration of the semiconductor device according to a second embodiment; and

FIG. 4 is a cross-sectional view illustrating an exemplary configuration a semiconductor device according to a modification.

### DETAILED DESCRIPTION

Embodiments provide a semiconductor device capable of preventing leakage of electromagnetic noise which is generated in a package.

In general, according to one embodiment, a semiconductor device includes a substrate comprising a substrate receiving surface, a side surface, and at least two ground wirings embedded therein and extending to, and exposed at, the side surface, a semiconductor chip mounted on the receiving surface of the substrate, a sealing resin layer over the substrate and the semiconductor chip, the sealing resin layer having an outer surface comprising an upper surface and a side surface, and a conductive shield layer located on the upper surface of the sealing resin layer, the side surface of the sealing resin layer, and the side surface of the substrate, and connected to the at least two ground wirings exposed at the side surface of the substrate, wherein the at least two ground wirings are separated from each other within the substrate, and connected to each other along the side surface of the substrate.

Hereinafter, embodiments according to the present disclosure will be described with reference to the drawings. The present disclosure is not limited to the embodiments. In the following embodiments, an upward and downward direction of a mounting substrate indicates a relative direction in a case where the mounting surface of the semiconductor chip faces upward, and this direction may be different from the upward and downward direction according to the direction of gravitational acceleration.

In the following embodiments, the description will be given about an example of a semiconductor device (semiconductor package) applied to a ball grid array (BGA), but the embodiment may be similarly applied even to a land grid array (LGA).

### First Embodiment

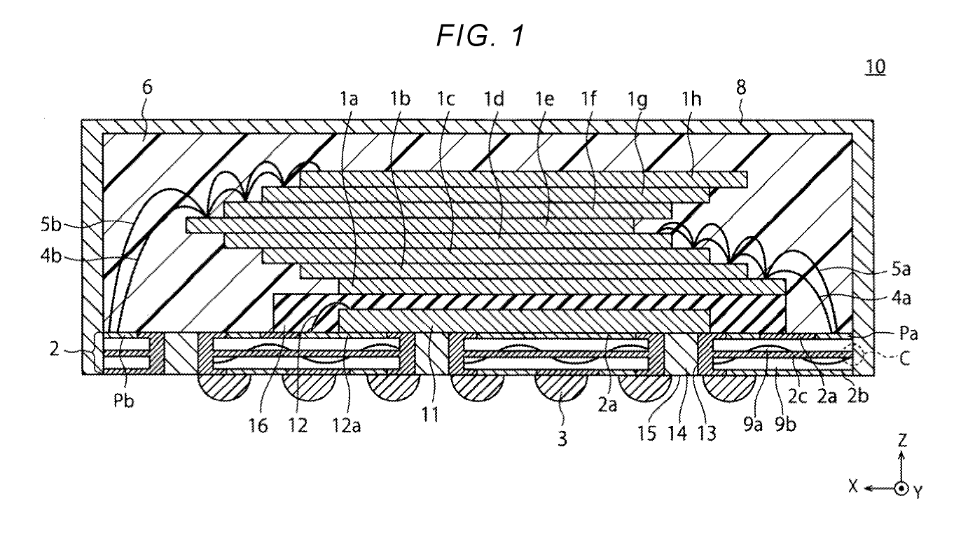

FIG. 1 is a cross-sectional view illustrating an example of a configuration of a semiconductor device 10 according to a first embodiment. The semiconductor device 10 includes amounting substrate 2, an external connection terminal (solder bumps 3), semiconductor chips 1a to 1h and 11, bonding wires 4a, 4b, 5a, 5b, and 12, a sealing resin layer 6, and a shield layer 8.

The mounting substrate 2 includes a multilayer wiring layer which is embedded in an insulating material. The mounting substrate 2 is also simply called a substrate. For example, the insulating material includes insulating layers 9a and 9b. As the insulating layers 9a and 9b, for example, an insulating material such as a glass epoxy resin is used. The multilayer wiring layer includes wiring layers 2a, 2b, and 2c for example. Examples of the wiring layers 2a, 2b, and 2c include a conductive metal such as gold, silver, copper, aluminum, nickel, palladium, and tungsten. In addition, the pad electrodes Pa and Pb are electrically connected to the wiring layers 2a, 2b, and 2c in the upper surface of the mounting substrate 2. The pad electrodes Pa and Pb are electrically connected to the semiconductor chips 1a to 1h via the bonding wires 4a, 4b, 5a, and 5b. The rear surface of the mounting substrate 2 is provided with a solder bump 3 as the external connection terminal) for example. The solder bump 3 is electrically connected to other semiconductor devices (not illustrated).

The wiring layer 2c is provided between the wiring layer 2a and the wiring layer 2b. One end of the wiring layer 2c is exposed at and extends along the side surface of the mounting substrate 2 and has a cut surface in a thickness direction (Z direction) of the mounting substrate 2 on both sides thereof in the Z direction. The cut surface of the wiring layer 2c is a surface which is cut by a dicing blade. The wiring layer 2c is provided as a ground wiring, and electrically connected to ground.

In addition, the mounting substrate 2 includes a via 15 which passes through the mounting substrate 2 to electrically connect to any one of the wiring layers 2a, 2b, and 2c between the wiring layers. The via 15 includes a conductor layer 13 which is formed in the inner surface of the through via hole passing through the mounting substrate 2 and a plugging member 14 which fills a hollow portion inside the conductor layer 13.

The semiconductor chips 1a to 1h and 11 are provided on the upper surface of the mounting substrate 2. The semiconductor chip 11 is bonded onto the upper surface of the mounting substrate 2 by, for example, a Die Attachment Film (DAF) (not illustrated). The semiconductor chip 11 is electrically connected to a pad electrode 12a via the bonding wire 12. The semiconductor chip 11 is, for example, a controller of a NAND Electrically Erasable Programmable Read Only Memory (EEPROM). The semiconductor chip 11 is covered by a resin layer 16.

The semiconductor chips 1a to 1h are provided on the upper side of the semiconductor chip 11 and staked on the resin layer 16. The semiconductor chips 1a to 1h are bonded onto the resin layer 16 or onto the other semiconductor chips 1a to 1g by the DAF. The semiconductor chips 1a to 1h are, for example, NAND EEPROM chips.

The semiconductor chips 1a to 1e are electrically connected to the pad electrode Pa by the bonding wires 4a and 5a. In addition, the semiconductor chips 1f to 1h are electrically connected to the pad electrode Pb by the bonding wires 4b and 5b.

The sealing resin layer 6 is provided on the upper surface of the mounting substrate 2 to cover the semiconductor chips 1a to 1h and 11 and the bonding wires 4a, 4b, 5a, 5b, and 12.

The shield layer 8 is provided to cover the upper surface of the sealing resin layer 6, the side surface of the sealing resin layer 6, and the side surface of the mounting substrate 2. The shield layer 8 is also provided in the side surface of the mounting substrate 2 and is connected to the wiring layer 2c.

The reason why the shield layer 8 is provided is as follows. Electromagnetic waves are radiated from the wiring layers of the semiconductor chips 1a to 1h and 11 and the mounting substrate 2. There is a concern that the electromagnetic waves may adversely affect devices external to the semiconductor device 10. Therefore, the shield layer 8 is provided to cover the sealing resin layer 6 and the side surface of the mounting substrate 2. The shield layer 8 blocks the electromagnetic waves from the inner portion of the semiconductor device 10 from passing therethrough. With this configuration, the electromagnetic waves from the semiconductor chips 1a to 1h and 11 and the wiring layer of the mounting substrate 2 are prevented from leaking to the outer side of the device.

It is desirable that the shield layer 8 be formed of a metal layer having a low resistance to effectively exert a function of shielding the electromagnetic waves. For example, a conductive metal such as copper, silver, nickel, stainless steel (SUS) or a stacked film made of plural materials from among these materials is used for the shield layer 8.

The external connection terminal, here a depicted as a bump 3, is provided in the lower surface of the mounting substrate 2 and is electrically connected to the wiring layer 2b of the mounting substrate 2. The external connection terminal 3 is, for example, a solder ball. Further, the wiring layer 2c as the ground wiring is electrically connected to an external ground of the semiconductor device 10 via the bump 3.

With such a configuration, the semiconductor device 10 transfers the electromagnetic waves to the ground and can prevent the electromagnetic waves from leaking to the outside of the package of the semiconductor device 10.

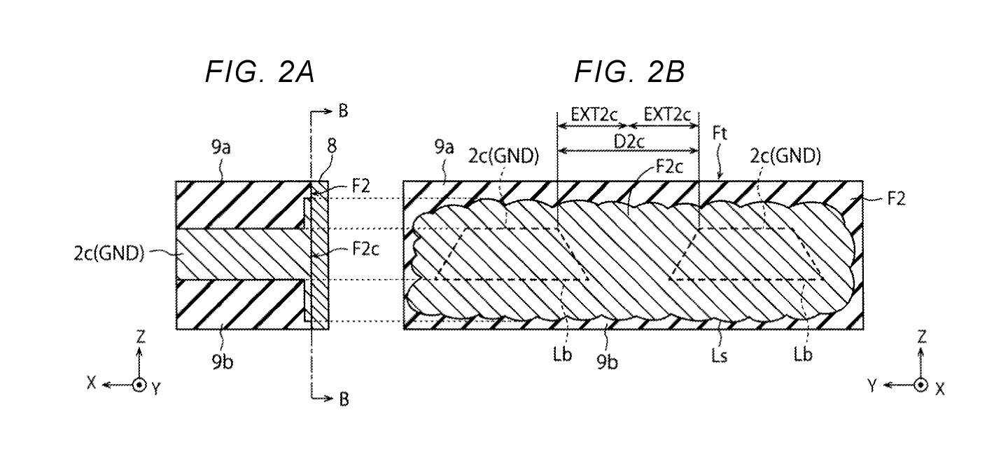

FIGS. 2A and 2B are cross-sectional views of the wiring layer 2c at the side surface of the mounting substrate 2 illustrated in FIG. 1. FIG. 2A is a magnified cross-sectional view of the area of the Circle C of FIG. 1 in the vicinity of the side surface of the mounting substrate 2 of FIG. 1. FIG. 2B is a cross-sectional view taken along line of B-B of FIG. 2A. In other words, FIG. 2B illustrates the side surface of the mounting substrate 2 with the shield layer 8 and is a cross-sectional view when viewed from an X direction of FIG. 1. Further, in FIG. 2B, the wiring layer 2c exposed to the side surface of the mounting substrate 2 when the shield layer 8 is removed is illustrated with a solid line Ls, and the wiring layer 2c in the inner portion of the mounting substrate 2 is illustrated with a broken line Lb. The inner portion of the mounting substrate 2 indicates an area surrounded by the insulating layers 9a and 9b of FIG. 2A.

As illustrated in FIG. 2A, the side surface of the wiring layer 2c exposed to a side surface F2 of the mounting substrate 2 is denoted by F2c. A side surface F2c of the wiring layer 2c is formed larger than the wiring layer 2c in the inner portion of the mounting substrate 2. Therefore, as illustrated in FIG. 2B, the area of the side surface F2c of the wiring layer 2c (an area of the region surrounded by Ls) is larger than an area (a sum of the area of the region surrounded by Lb) of the wiring layer 2c in the inner portion of the mounting substrate 2. When the mounting substrate 2 is cut out by the dicing blade, the wiring layer 2c abuts on the dicing blade and is smeared or spread over the end of the insulating layers 9a, 9b.

In addition, as illustrated in FIG. 2B, a plurality of wiring layers 2c are arranged in the same wiring layer in the side surface F2 of the mounting substrate 2. In other words, the plural wiring layers 2c are spaced apart in a Y direction in the mounting substrate 2. Additionally, the plural wiring layers 2c are arranged in a direction substantially in parallel to an upper surface Ft of the mounting substrate 2 in the side surface F2 of the mounting substrate 2. The plural wiring layers 2c are a ground wiring and can be electrically connected to the ground. Further, in FIG. 2B, two wiring layers 2c are illustrated, but three or more wiring layers 2c may be provided between the insulating layers 9a and 9b. In addition, since the wiring layers 2c are the ground wiring, there is no problem even if the layers are short-circuited to each other.

As the broken line Lb illustrated in of FIG. 2B, the plural wiring layers 2c are separated from each other in the inner portion of the mounting substrate 2. However, as illustrated with the solid line Ls, the plural wiring layers 2c are connected to each other and widely smeared or spread in the Y direction in the side surface F2c substantially flush with the side surface F2 of the mounting substrate 2. In other words, the adjacent plural wiring layers 2c are short-circuited and connected to each other in the vicinity of the contact surface between the side surface of the mounting substrate 2 and the shield layer 8. In this case, a contact area (an area of the region surrounded by the solid line Ls) between the plural wiring layers 2c and the shield layer 8 becomes larger than a sum of areas of the cross sections of the plural wiring layers 2c (a sum of areas of the regions surrounded by the broken line Lb) in the cross surface which is substantially parallel to the side surface F2 of the mounting substrate 2 in the mounting substrate 2.

With this configuration, the contact area between the wiring layer 2c and the shield layer 8 becomes large, and a connection state of both layers to the outer shield 8 can be improved. In other words, a contact resistance between the shield layer 8 and the wiring layer (ground wiring) 2c can be lowered. As a result, the semiconductor device 10 can cause most of the electromagnetic waves to release to the ground, so that the leakage of the electromagnetic waves to the outside of the semiconductor device 10 can be reduced. In addition, since the adjacent plural wiring layers 2c are widened and connected in the side surface F2 of the mounting substrate 2, the wiring layer 2c itself can have an effect of electromagnetic shield. As a result, the semiconductor device 10 can have further reduced leakage of the electromagnetic waves.

As a semiconductor package is miniaturized, the mounting substrate 2 is also miniaturized. Therefore, an interval D2c of the adjacent plural wiring layers 2c becomes narrow. When the mounting substrate 2 is cut out by the dicing blade, the adjacent plural wiring layers 2c may become naturally connected by smearing or spreading of the material thereof across the adjacent end surfaces of the adjacent insulating layers 9 (9a, 9b) by the cutting wheel during dicing of the device or the substrate 2. In this way, the interval D2c of the adjacent wiring layers 2c is desirably equal to or less than two times a spreading width EXT2 of the wiring layer 2c in the side surface F2 of the mounting substrate 2 in order to connect the plural wiring layers 2c during dicing in a self-aligned manner. With this configuration, after dicing, the plural wiring layers 2c can be widened in the side surface F2 of the mounting substrate 2 and be connected in a self-aligned manner.

### Second Embodiment

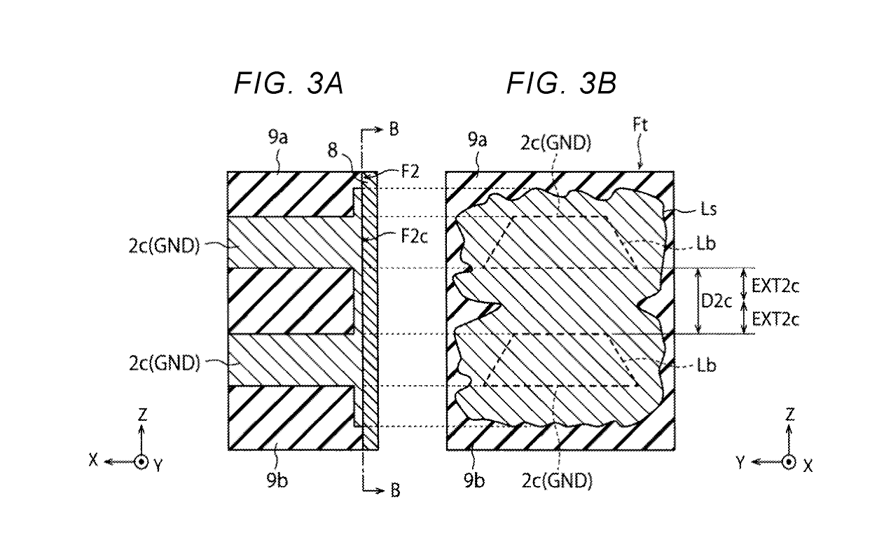

FIGS. 3A and 3B are cross-sectional views of an exemplary configuration of the semiconductor device 10 according to a second embodiment. FIG. 3A is a magnified cross-sectional view of the portion of the device 10 within the Circle C of FIG. 1 in the vicinity of the side surface of the mounting substrate 2. FIG. 3B is a cross-sectional view taken along line B-B of FIG. 3A. FIG. 3B illustrates the side surface of the mounting substrate 2 with the shield layer 8 removed, when viewed from the X direction of FIG. 1. Further, in FIG. 3B, the edge of the wiring layer 2c exposed to the side surface of the mounting substrate 2 with the shield layer 8 removed is depicted by the solid line Ls, and the outline of the wiring layer 2c in the inner portion of the mounting substrate 2 is depicted by the broken line Lb.

The second embodiment is different from the first embodiment in that the plural layers 2c depicted by the broken line are spaced from one another in a vertical direction (Z direction). The other configurations of the semiconductor device 10 of the second embodiment may be similar to those corresponding to the semiconductor device 10 of the first embodiment.

Similarly to the first embodiment, the side surface F2c of the wiring layer 2c is formed larger than that of the wiring layer 2c in the inner portion of the mounting substrate 2. Therefore, the area (an area of the region surrounded by Ls) of the side surface F2c of the wiring layer 2c is larger than the area (a sum of areas of the regions surrounded by Lb) of the wiring layer 2c in the inner portion of the mounting substrate 2.

In addition, as illustrated in FIG. 3B, the plural wiring layers 2c are spaced apart in the vertical direction as the different wiring layer in the side surface F2 of the mounting substrate 2. In other words, the plural wiring layers 2c are arranged spaced from each other in the Z direction in the mounting substrate 2. In other words, the plural wiring layers 2c are spaced from each other in a direction substantially perpendicular to the upper surface Ft of the mounting substrate 2 in the side surface F2 of the mounting substrate 2. The plural wiring layers 2c serve as the ground wirings and can be electrically connected to the ground.

As illustrated with the broken line Lb of FIG. 3B, the plural wiring layers 2c are separated from each other in the mounting substrate 2. However, as illustrated with the solid line Ls, the plural wiring layers 2c are widely spread out, in the X direction and in the Z direction along the side surface F2c substantially flush with the side surface F2 of the mounting substrate 2 and connected to each other. In other words, the adjacent plural wiring layers 2c are short-circuited and connected to each other in the vicinity of the contact surface between the side surface of the mounting substrate 2 and the shield layer 8. In this case, a contact area (an area of the region surrounded by the solid line Ls) between the plural wiring layers 2c and the shield layer 8 becomes larger than a sum of areas of the cross sections of the plural wiring layers 2c (a sum of areas of the regions surrounded by the broken line Lb) in the cross surface which is substantially parallel to the side surface F2 of the mounting substrate 2 in the mounting substrate 2.

With this configuration, the contact area between the wiring layer 2c and the shield layer 8 becomes large, and a connection state of both layers can be improved. In other words, a contact resistance between the shield layer 8 and the wiring layer (ground wiring) 2c can be lowered. As a result, the semiconductor device 10 can cause most of the electromagnetic waves to be released to the ground, so that the leakage of the electromagnetic waves to the outside of the semiconductor device 10 can be reduced. In addition, since the adjacent plural wiring layers 2c are widened and connected on the side surface F2 of the mounting substrate 2, the wiring layer 2c itself can have the effect of an electromagnetic shield. As a result, the semiconductor device 10 can reduce the leakage of the electromagnetic waves still more.

The interval D2c of the wiring layers 2c adjacent in the Z direction is desirably equal to or less than two times a spreading width EXT2 of the wiring layer 2c in the side surface F2 of the mounting substrate 2 in order to connect the plural wiring layers 2c by dicing in a self-aligned manner. With this configuration, after dicing, the plural wiring layers 2c can be widened in the side surface F2 of the mounting substrate 2 and be connected in a self-aligned manner.

Modification

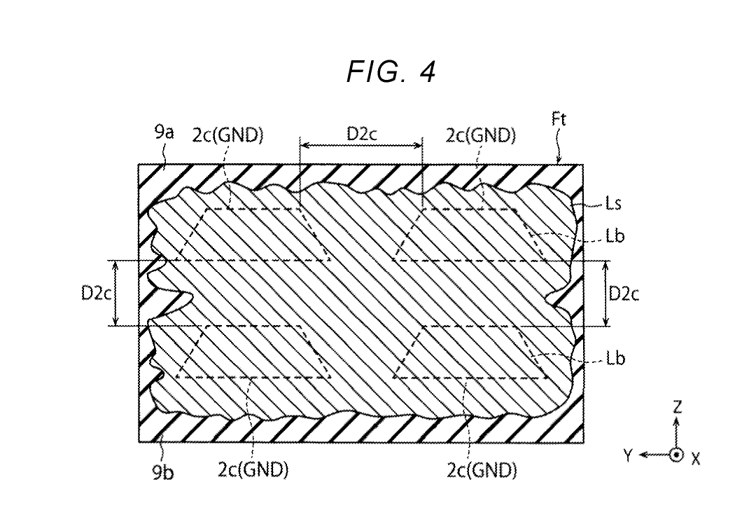

FIG. 4 is a cross-sectional view illustrating an exemplary configuration of the semiconductor device 10 according to a modification. The modification is configured by combining the first embodiment and the second embodiment. In the modification, the plural wiring layers 2c are spaced from one another in a direction substantially parallel to, and substantially perpendicular to, the upper surface Ft of the mounting substrate 2 along the side surface F2 of the mounting substrate 2. In other words, the plural wiring layers 2c are provided in the same wiring layer, and a different wiring layer, at the side surface F2 of the mounting substrate 2. Then, the plural wiring layers 2c are connected to each other in a direction substantially parallel and perpendicular to the upper surface Ft of the mounting substrate 2.

In this way, the plural wiring layers 2c at the side surface F2 (in the Z direction and the Y direction) may be connected to each other. With this configuration, the contact area between the wiring layer 2c and the shield layer 8 becomes large, and a connection state of both layers can be improved. As a result, the semiconductor device 10 can cause most of electromagnetic waves to release to the ground, so that the leakage of the electromagnetic waves to the outside of the semiconductor device 10 can be reduced. In addition, since the adjacent plural wiring layers 2c are widened and connected along the side surface F2 of the mounting substrate 2, the wiring layer 2c itself can have the effect of an electromagnetic shield.

Further, there are illustrated four wirings in FIG. 4, but five or more wirings may be two-dimensionally disposed along or at the side surface F2. With this configuration, the entire side surface F2 of the mounting substrate 2 may be covered with the metal wiring layer 2c. As a result, the semiconductor device 10 can further reduce the leakage of the electromagnetic waves.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate comprising a substrate receiving surface, a side surface, and at least two ground wirings embedded therein and extending to, and exposed at, the side surface;
a semiconductor chip mounted on the receiving surface of the substrate;
a sealing resin layer over the substrate and the semiconductor chip, the sealing resin layer having an outer surface comprising an upper surface and a side surface; and
a conductive shield layer located on the upper surface of the sealing resin layer, the side surface of the sealing resin layer, and the side surface of the substrate, and connected to the at least two ground wirings exposed at the side surface of the substrate, wherein
the at least two ground wirings are separated from each other within the substrate and connected to each other along the side surface of the substrate.

2. The semiconductor device according to claim 1, wherein the at least two ground wirings are connected to each other at a location between the side surface of the substrate and the shield layer.

3. The semiconductor device according to claim 1, wherein the at least two ground wirings within the substrate each have a cross sectional area substantially parallel to the side surface of the substrate, and an area of contact between the at least two ground wirings and the shield layer is larger than a sum of cross sectional areas of the at least two ground wirings within the substrate.

4. The semiconductor device according to claim 1, wherein the spacing between the at least two ground wirings is equal to or less than two times a spreading width of the ground wiring along the side surface of the substrate when the substrate is cut through the ground wiring.

5. The semiconductor device according to claim 1, wherein the at least two ground wirings are spaced from one another in a direction substantially parallel to the receiving surface of the substrate within the substrate, and connected to each other outside of the substrate.

6. The semiconductor device according to claim 1, wherein the at least two ground wirings are spaced from one another in a direction substantially perpendicular to the receiving surface of the substrate within the substrate, and connected to each other outside of the substrate.

7. A semiconductor device, comprising:
a substrate comprising a substrate receiving surface, a side surface, and at least two ground wirings, each having a first portion extending within the substrate and a second portion along the side surface of the substrate;
a semiconductor chip mounted on the receiving surface of the substrate;
a sealing resin layer located over the substrate and the semiconductor chip, the sealing resin layer having an outer surface; and
a conductive shield layer located over the outer surface of the sealing resin layer and over the side surface of the substrate, and connected to the second portion of the at least two ground wirings along the side surface of the substrate, wherein
the first portions of the at least two ground wirings are spaced from one another, and the second portions of the at least two ground wirings contact each other along the side surface of the substrate.

8. The semiconductor device according to claim 7, wherein the at least two ground wirings extend in a first direction across the receiving surface of the substrate.

9. The semiconductor device according to claim 7, wherein the first and second portions of the at least two ground wirings comprise the same material.

10. The semiconductor device according to claim 9, wherein the first and second portions of each of the at least two ground wirings form a continuous wiring.

11. The semiconductor device according to claim 9, wherein the second portions of the at least two ground wirings are spread over the side surface of the substrate.

12. The semiconductor device according to claim 7, wherein:
the first portions of the at least two ground wirings extend a first distance in a second direction crossing the first direction;
the second portions of the at least two ground wirings extend a second distance in the second direction crossing the first direction; and
the second distance is greater than the first distance.

13. The semiconductor device according to claim 12, wherein the second direction is perpendicular to the receiving surface of the substrate.

14. The semiconductor device according to claim 13, wherein at least two of the at least two first portions of the ground wire are spaced from each other in the second direction.

15. The semiconductor device according to claim 12, wherein the second direction is parallel to the receiving surface of the substrate.

16. The semiconductor device according to claim 15, wherein at least two of the at least two first portions of the ground wire are spaced from each other in the second direction.

17. A method of manufacturing a semiconductor device, comprising:
providing a mounting substrate having at least two wiring layers that are spaced from each other and extending within the mounting substrate;
cutting across and through the mounting substrate, and simultaneously spreading a portion of the at least two wiring layers over the resulting side surface of the cut portion of the mounting substrate; and
covering the mounting substrate, including the side surface, with a conductive shielding layer.

18. The method according to claim 17, further comprising forming a resin layer over the mounting substrate before cutting the mounting substrate.

19. The method according to claim 18, further comprising mounting at least one semiconductor chip on the mounting substrate before forming the resin layer, whereby the semiconductor chip is covered by the resin layer.

20. The method according to claim 17, wherein the at least two wiring layers comprise a metal.
